(19) United States
(12) Patent Application Publication
(10) Pub. No.: US 2017/0110392 A1
(43) Pub. Date: Apr. 20, 2017

(54) SEMICONDUCTOR PACKAGE STRUCTURE AND METHOD FOR MANUFACTURING THE SAME STRUCTURE

(71) Applicant: ADVANCED SEMICONDUCTOR ENGINEERING, INC., KAOHSIUNG (TW)

(72) Inventors: Chun-Hung LIN, Kaohsiung (TW); Yi-Ting CHEN, Kaohsiung (TW); Shih-Ming HUANG, Kaohsiung (TW); Ching-Rong LIN, Kaohsiung (TW)

(21) Appl. No.: 14/884,582

(22) Filed: Oct. 15, 2015

(51) Int. Cl. H01L 23/498; H01L 21/48; H01L 21/56; H01L 23/31

(52) U.S. Cl. CPC H01L 23/49827; H01L 23/3157; H01L 23/49866; H01L 23/49838; H01L 21/4853; H01L 21/486; H01L 21/56

(57) ABSTRACT

A semiconductor package structure includes a first semiconductor substrate, a second semiconductor substrate, a semiconductor die electrically connected to the first semiconductor substrate, an interconnection element and an encapsulant. The first semiconductor substrate includes a first top pad, and the second semiconductor substrate includes a second bottom pad. The interconnection element connects the second bottom pad and the first top pad. The interconnection element includes a first cupped portion and a second arcuate portion, where the first portion is connected to the first top pad and the second portion is connected to the second bottom pad. The first portion and the second portion together define the interconnection element as a monolithic component. The encapsulant is disposed between the first semiconductor substrate and the second semiconductor substrate, and covers the semiconductor die and the interconnection element.

### BACKGROUND

1. Field of the Disclosure

The present disclosure relates to a semiconductor package structure and a semiconductor process, and more particularly to a stacked semiconductor package structure and a method for manufacturing the same.

2. Description of the Related Art

A conventional manufacturing process of making a stacked semiconductor package structure may not provide for a fine enough pitch for a desired application, or portions of the structure may warp or peel, or unwanted bridging may occur between neighboring interconnections. Improved manufacturing techniques are thus desirable.

### SUMMARY

In an aspect, a semiconductor package structure includes a first semiconductor substrate, a second semiconductor substrate, a semiconductor die electrically connected to the first semiconductor substrate, an interconnection element and an encapsulant. The first semiconductor substrate includes a first top pad, and the second semiconductor substrate includes a second bottom pad. The interconnection element connects the second bottom pad and the first top pad. The interconnection element connects the second bottom pad and the first top pad. The interconnection element includes a first cupped portion and a second arcuate portion, where the first portion is connected to the first top pad and the second portion is connected to the second bottom pad. The first portion and the second portion together define the interconnection element as a monolithic component. The encapsulant is disposed between the first semiconductor substrate and the second semiconductor substrate, and covers the semiconductor die and the interconnection element.

In another aspect, a semiconductor package structure includes a first semiconductor substrate, a second semiconductor substrate, a semiconductor die electrically connected to the first semiconductor substrate, at least one interconnection element, and an encapsulant. The first semiconductor substrate includes at least one first top pad, and the second semiconductor substrate includes at least one second bottom pad corresponding to a respective first top pad. The interconnection element connects the second bottom pad and the first top pad. A material of the interconnection element is consistent throughout a volume of the interconnection element, and the material includes Sn in an amount ranging from about 95 wt % to about 99.8 wt %. The encapsulant is disposed between the first semiconductor substrate and the second semiconductor substrate, and covers the semiconductor die and the interconnection element.

In another aspect, a method for manufacturing a semiconductor package structure includes (a) providing a first semiconductor substrate and a semiconductor die, wherein the semiconductor die is electrically connected to the first semiconductor substrate, and the first semiconductor substrate includes at least one first top pad and at least one pre-solder disposed on a respective first top pad; (b) providing a second semiconductor substrate, wherein the second semiconductor substrate includes at least one second bottom pad and at least one solder ball disposed on a respective second bottom pad, wherein the melting point of the solder ball is higher than that of the pre-solder; (c) disposing the second semiconductor substrate on the first semiconductor substrate, wherein the solder ball contacts the pre-solder; (d) conducting a heating process at a first temperature between the melting point of the solder ball and the melting point of the pre-solder so that the pre-solder is softened and adhered to the solder ball; and (e) applying an encapsulant to a space between the first semiconductor substrate and the second semiconductor substrate to encapsulate the semiconductor die.

### BRIEF DESCRIPTION OF THE DRAWINGS

FIG. 1 illustrates a cross-sectional view of a semiconductor package structure according to an embodiment of the present disclosure.

FIG. 2 illustrates an enlarged view of section A shown in FIG. 1 according to an embodiment of the present disclosure.

FIG. 3 illustrates an enlarged view of an interconnection element according to an embodiment of the present disclosure.

FIG. 4 illustrates an enlarged view of an interconnection element according to an embodiment of the present disclosure.

FIG. 5, FIG. 6, FIG. 7, FIG. 8, FIG. 9 and FIG. 10 illustrate a semiconductor process according to an embodiment of the present disclosure.

FIG. 11 illustrates a semiconductor process according to an embodiment of the present disclosure.

### DETAILED DESCRIPTION

The present disclosure provides an improved semiconductor package structure with reduced warping, peeling, and bridging, and improved techniques for manufacturing the semiconductor package structure. The semiconductor package structure and techniques of the present disclosure are suitable for fine-pitch applications.

A manufacturing process of making a stacked semiconductor package structure may begin with bonding a die and solder balls to an upper surface of a lower substrate, followed by forming a molding material on the upper surface of the lower substrate to encapsulate the die and solder balls. Once the molding material is solidified, openings may be formed on an upper surface of the molding material to expose an upper portion of each of the solder balls. Next, an upper substrate may be disposed on the molding material such that solder on a lower surface of the upper substrate is in contact with the solder balls. At a first heating stage, the solder and the solder balls may then be fused in an oven to form a number of interconnection elements. When the semiconductor package structure is moved to the oven for the first heating stage, the lower surface of the upper substrate is in contact with, but not bonded to, the molding material and the solder is in contact with, but not bonded to, the solder balls. Consequently, the upper substrate may move relative to the molding material during the transportation of the semiconductor package structure.

To address such concerns, interconnection elements between the upper substrate and the lower substrate may be formed in an early stage in the manufacturing process, followed by a molding stage to form a molding material between the upper and lower substrates. Such interconnection elements may be formed, for example, by fusing the solder balls on the upper substrate and the lower substrate. However, because the solder balls of the upper substrate and the lower substrate are melted concurrently, the melted interconnection elements may not provide a sufficient standoff between the upper substrate and the lower substrate. Therefore, height control may be difficult between the upper and lower substrates.

To address such concerns, the interconnection element may be formed by a coated metal ball, such as a copper-core ball coated with a solder. However, during the reflow process, the outer coat of solder on the metal ball can flow downward along the ball so that bonding between the interconnection element and the upper substrate may crack due to a loss of solder, which may diminish the electrical connection between the interconnection element and the upper substrate. Further, if the outer solder flows downward, accumulated solder on the bottoms of adjacent coated metal balls may touch and cause a bridge.

To address the above concerns, an improved interconnection element is formed that provides for strong bonding while also providing a support and standoff between two substrates and is tolerant to misalignment of the two substrates. The techniques described reduce substrate warp and peel, and reduce unwanted bridging between adjacent interconnection elements.

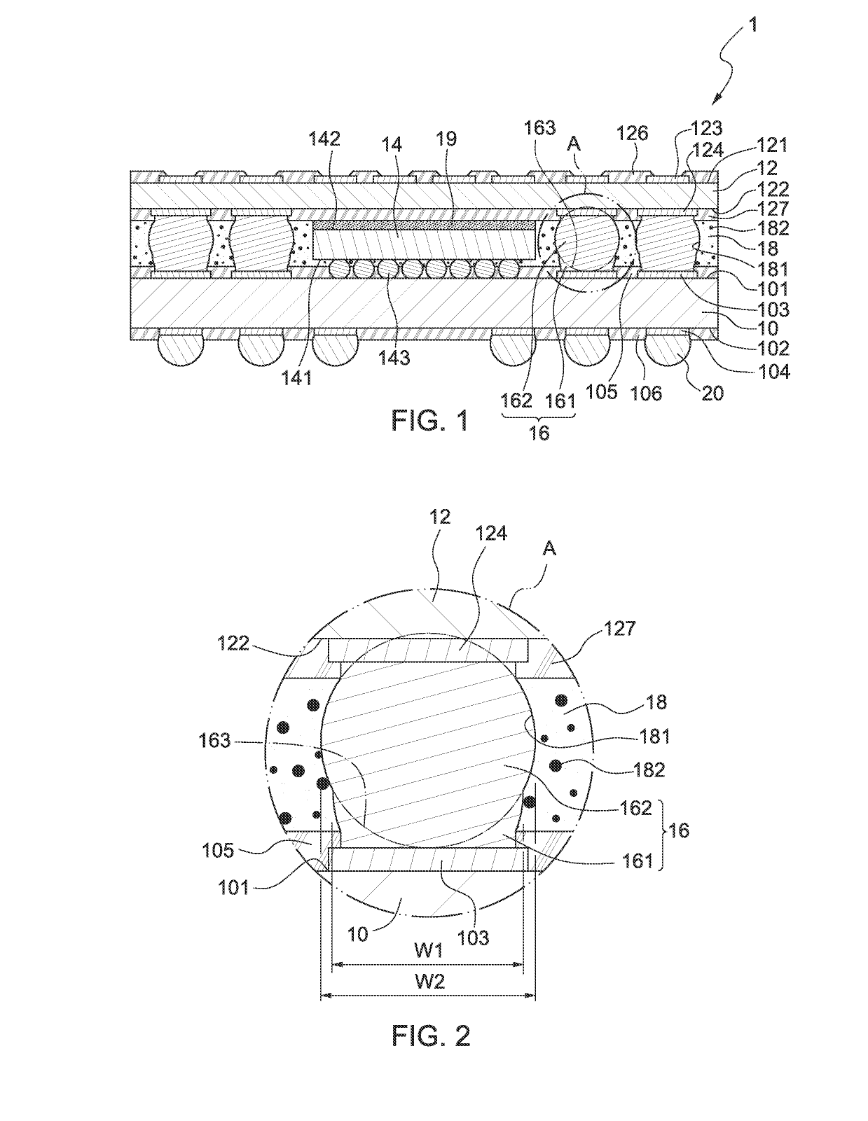

FIG. 1 illustrates a cross-sectional view of a semiconductor package structure 1 according to an embodiment of the present disclosure. The semiconductor package structure 1 includes a first semiconductor substrate 10, a second semiconductor substrate 12, a semiconductor die 14, at least one interconnection element 16, an encapsulant 18 and bottom solder balls 20.

The first semiconductor substrate 10 includes an upper surface 101, a lower surface 102, at least one first top pad 103 and at least one first bottom pad 104. In this embodiment, the first semiconductor substrate 10 is a package substrate, and includes multiple first top pads 103 and multiple first bottom pads 104. The first bottom pads 104 are disposed on the lower surface 102 of the first semiconductor substrate 10, and the first top pads 103 are disposed on the upper surface 101 of the first semiconductor substrate 10. Ones of the first bottom pads 104 electrically connect to ones of the first top pads 103.

In the embodiment illustrated in FIG. 1, the first semiconductor substrate 10 further includes a first upper dielectric layer 105 and a first lower dielectric layer 106. A material of the first upper dielectric layer 105 and/or the first lower dielectric layer 106 is, for example, a solder mask or other suitable dielectric material. A portion of the upper surface 101 of the first semiconductor substrate 10 is covered by the first upper dielectric layer 105, and a portion of the lower surface 102 of the first semiconductor substrate 10 is covered by the first lower dielectric layer 106. The first top pads 103 are exposed by the first upper dielectric layer 105, and the first bottom pads 104 are exposed by the first lower dielectric layer 106.

In one or more embodiments, one or both of the first upper dielectric layer 105 and the first lower dielectric layer 106 are omitted.

In the embodiment illustrated in FIG. 1, the second semiconductor substrate 12 includes an upper surface 121, a lower surface 122, at least one second top pad 123 and at least one second bottom pad 124. The upper surface 101 of the first semiconductor substrate 10 faces the lower surface 122 of the second semiconductor substrate 12. In this embodiment, the second substrate 12 is a package substrate or an interposer, and includes multiple second top pads 123 and multiple second bottom pads 124. The second top pads 123 are disposed on the upper surface 121 of the second semiconductor substrate 12, and the second bottom pads 124 are disposed on the lower surface 122 of the second substrate 12. Ones of the second top pads 123 electrically connect to ones of the second bottom pads 124.

Further in this embodiment, the second semiconductor substrate 12 includes a second upper dielectric layer 126 and a second lower dielectric layer 127. A material of the second upper dielectric layer 126 and/or the second lower dielectric layer 127 is, for example, a solder mask or other suitable dielectric material. As shown in FIG. 1, a portion of the upper surface 121 of the second semiconductor substrate 12 is covered by the second upper dielectric layer 126, and a portion of the lower surface 122 of the second semiconductor substrate 12 is covered by the second lower dielectric layer 127. The second top pads 123 are exposed by the second upper dielectric layer 126, and the second bottom pads 124 are exposed by the second lower dielectric layer 127.

In one or more embodiments, one or both of the second upper dielectric layer 126 and the second lower dielectric layer 127 are omitted.

The semiconductor die 14 is electrically connected to the upper surface 101 of the first semiconductor substrate 10. In the embodiment illustrated in FIG. 1, the semiconductor die 14 is attached to the upper surface 101 of the first semiconductor substrate 10 by flip-chip bonding, and bumps 143 are used to connect an active surface 141 of semiconductor die 14 and the upper surface 101 of the first semiconductor substrate 10.

The interconnection elements 16 connect ones of the first top pads 103 and ones of the second bottom pads 124. Each of the interconnection elements 16 has a first portion 161 and a second portion 162, where the second portion 162 corresponds to at least a majority by weight or volume of the interconnection elements 16. In an embodiment, a pre-solder (corresponding to the first portion 161) and a solder ball (corresponding to the second portion 162) are fused together to form the interconnection element 16. That is, the interconnection element 16 is a monolithic component formed by fusing two components (pre-solder and solder ball) together, such that there is not a detectable boundary between the first portion 161 and the second portion 162. A curved imaginary surface 163 is shown in FIG. 1 to indicate the first portion 161 and the second portion 162 of the fused interconnection element 16, where the first portion 161 is cupped, and the second portion 162 is arcuate, for example, approximately spherical. Because of the fusing of the pre-solder and solder ball, a material of the first portion 161 is substantially the same as a material of the second portion 162 along the curved imaginary surface 163. The first portion 161 is connected to the first top pad 103. The second portion 162 is connected to the second bottom pad 124.

Traces (not shown) and vias or other interconnection components (not shown) may be used to electrically connect the first top pads 103 and the first bottom pads 104 or to electrically connect the second top pads 123 and the second bottom pads 124.

The encapsulant 18 is disposed between the first semiconductor substrate 10 and the second semiconductor substrate 12. In the embodiment shown in FIG. 1, the encapsulant 18 is disposed between the second lower dielectric layer 127 and the first upper dielectric layer 105 and encapsulates (covers) the semiconductor die 14 and the interconnection elements 16. The encapsulant 18 adheres to both the second lower dielectric layer 127 and the first upper dielectric layer 105. In embodiments in which the second lower dielectric layer 127 and the first upper dielectric layer 105 are of similar materials, the adhesion force between the encapsulant 18 and the second lower dielectric layer 127 can be substantially the same as the adhesion force between the encapsulant 18 and the first upper dielectric layer 105. It is noted that if the second lower dielectric layer 127 and the first upper dielectric layer 105 are omitted, the encapsulant 18 adheres to both the upper surface 101 of the first semiconductor substrate 10 and the lower surface 122 of the second semiconductor substrate 12. In embodiments in which the first semiconductor substrate 10 and the second semiconductor substrate 12 are of similar materials, an adhesion force between the encapsulant 18 and the upper surface 101 can be substantially the same as an adhesion force between the encapsulant 18 and the lower surface 122.

In the embodiment shown in FIG. 1, the encapsulant 18 defines accommodation spaces 181 to accommodate respective interconnection elements 16. A profile of each of the sidewalls of the accommodation spaces 181 is conformal to the respective interconnection element 16, such that the entire outer surface of the interconnection element 16 is in contact with the sidewall of the respective accommodation space 181. That is, the profile of each of the sidewalls of the accommodation spaces 181 is defined by the respective interconnection element 16. Accordingly, each of the interconnection elements 16 is tightly encapsulated by the encapsulant 18. In one or more embodiments, the encapsulant 18 further includes fillers 182 (e.g., silica oxide) of various radii. The fillers 182 are substantially uniformly distributed within the encapsulant 18. The bottom solder balls 20 are positioned on the first bottom pads 104 to electrically connect to an external component or surface.

The semiconductor package structure 1 further includes an adhesive layer 19 disposed between a back surface 142 of the semiconductor die 14 and the second semiconductor substrate 12. The adhesive layer 19 adheres to both the back surface 142 of the semiconductor die 14 and the second lower dielectric layer 127. It is noted that if the second lower dielectric layer 127 is omitted, the adhesive layer 19 adheres to both the back surface 142 of the semiconductor die 14 and the lower surface 122 of the second semiconductor substrate 12. The adhesive layer 19 may be formed, for example, by curing a liquid adhesive, or, for another example, the adhesive layer 19 may be a film structure. It is noted that the adhesive layer 19 may be omitted.

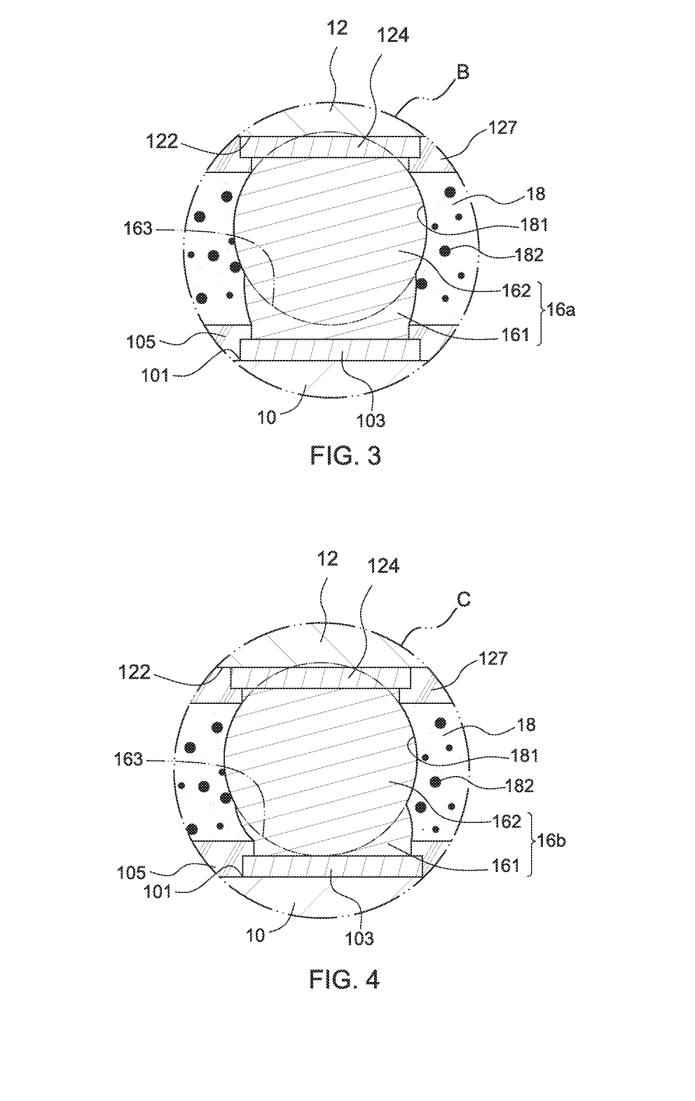

FIG. 2 illustrates an enlarged view of a section A shown in FIG. 1 according to an embodiment of the present disclosure. The cupped first portion 161 has a lateral maximum width W1. The arcuate second portion 162 has a lateral maximum width W2, which is the diameter of a sphere. The lateral maximum width W2 is greater than or equal to the lateral maximum width W1. A curvature of an imaginary surface 163 between the second portion 162 and the first portion 161 is substantially the same as, and continuous with, the curvature of the side surface of the second portion 162.

As shown in FIG. 2, the first portion 161 (corresponding to the pre-solder) extends upward along the periphery outer surface of the second portion 162 (corresponding to the solid solder ball). Therefore, the curvature of a side surface of the second portion 162 is discontinuous with a curvature of the side surface of the first portion 161. In other words, the side surface of the interconnection element 16 may include an upper side surface (e.g., the side surface of the second portion 162) and a lower side surface (e.g., the side surface of the first portion 161), and the curvature of the upper side surface is discontinuous with that of the lower side surface. That is, the whole side surface of the interconnection element 16 does not have a single curvature, and there is an intersecting point between the upper side surface (e.g., the side surface of the second portion 162) and the lower side surface (e.g., the side surface of the first portion 161). In the embodiment of FIG. 2, the second portion 162 is approximately spherical, such that, for example, a curvature along the side surface of the second portion 162 varies by less than or equal to ±10% of an average curvature of the side surface, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

In the embodiment illustrated in FIG. 2, the curved imaginary surface 163 contacts the first top pad 103. The interconnection element 16 is symmetrical about a vertical axis (in the orientation shown). Further, as shown in FIG. 2, the second bottom pad 124 is located above, and aligned with, the first top pad 103, and a geometrical central axis of the first top pad 103 substantially aligns with a geometrical central axis of the second portion 162 of the interconnection element 16.

In one or more embodiments, the interconnection element 16 contains tin (Sn) in an amount ranging from about 95 percent by weight (wt %) to about 99.8 wt %. In one or more embodiments, a material of the interconnection element 16 is consistent throughout a volume of the interconnection element 16, such that, for example, a material of the first portion 161 has a first tin content, a material of the second portion 162 has a second tin content, and the first tin content is substantially the same as the second tin content.

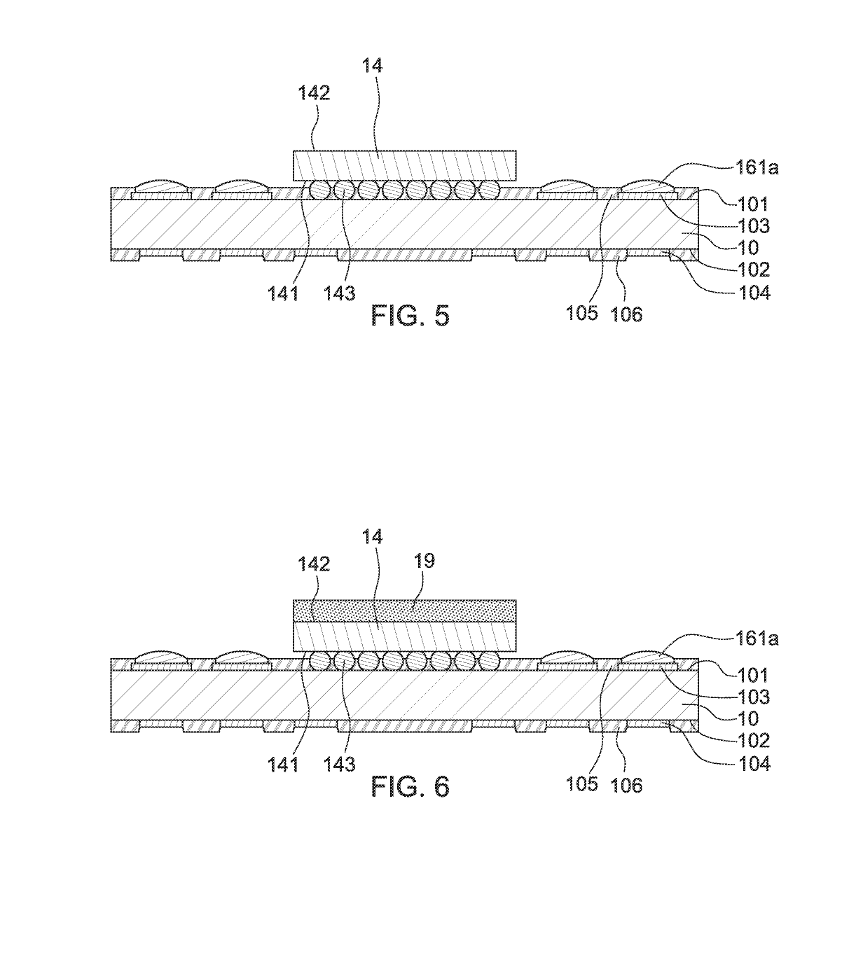

FIG. 3 illustrates an enlarged view B of an interconnection element 16a according to an embodiment of the present disclosure. The interconnection element 16a of this embodiment is similar to the interconnection element 16 as shown in FIG. 2, except that the curved imaginary surface 163 does not contact the first top pad 103. During manufacturing, the second portion 162 is pushed up by the cohesion force of the melted first portion 161, so that the second portion 162 is lifted from the first top pad 103 a short distance.

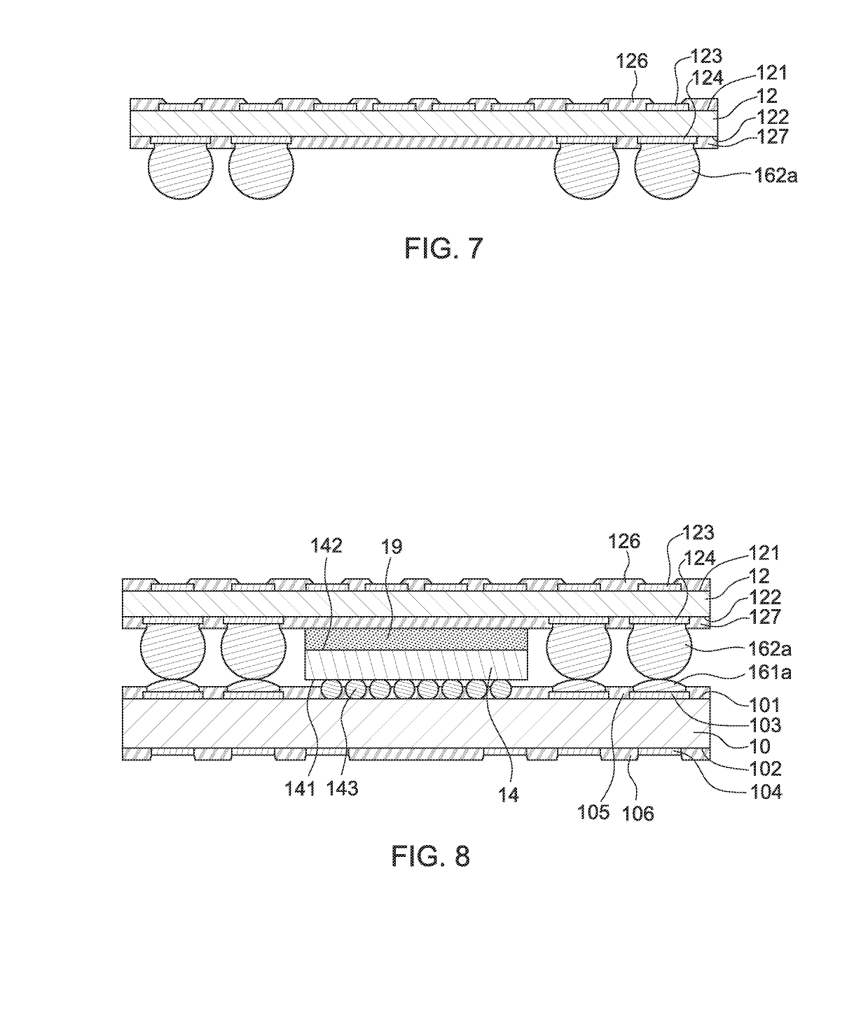

FIG. 4 illustrates an enlarged view C of an interconnection element 16b according to an embodiment of the present disclosure. The interconnection element 16b of this embodiment is similar to the interconnection element 16 as shown in FIG. 2, and the difference is described as follows. In this embodiment, the second bottom pad 124 is shifted with respect to the first top pad 103. Therefore, there is an offset between a geometrical central axis of the first top pad 103 and a geometrical central axis of the second portion 162 of the interconnection element 16b. Therefore, the interconnection element 16b is not symmetrical around a vertical axis (in the orientation shown) through the interconnection element 16b. As shown by this embodiment, an offset between the second bottom pad 124 and the first top pad 103 does not result in a bridge with an adjacent interconnection element 16b, because the amount of the pre-solder (corresponding to the first portion 161) is relatively small in the first instance, and because, rather than extending horizontally to adjacent interconnection elements 16b during manufacture, the pre-solder extends upward along the periphery outer surface of the solder ball (corresponding to the second portion 162) due to an interface affinity between the pre-solder and the solder ball.

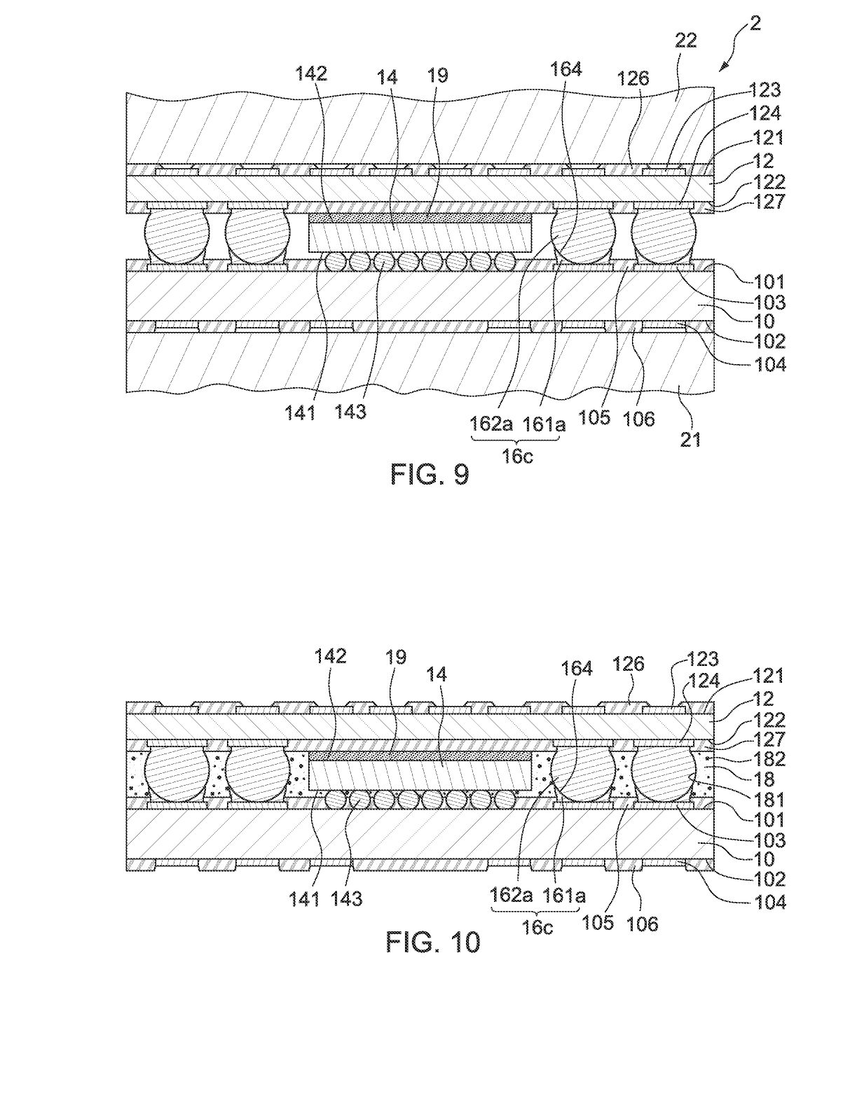

FIGS. 5 to 10 illustrate a semiconductor manufacturing process according to an embodiment of the present disclosure. Referring to FIG. 5, a semiconductor die 14 and a first semiconductor substrate 10 are provided.

The semiconductor die 14 is electrically connected to an upper surface 101 of the first semiconductor substrate 10. In this embodiment, the semiconductor die 14 is attached to the upper surface 101 of the first semiconductor substrate 10 by flip-chip bonding, and bumps 143 are used to connect an active surface 141 of the semiconductor die 14 and the upper surface 101 of the first semiconductor substrate 10.

Then, pre-solders 161a are formed on respective first top pads 103 disposed on the upper surface 101 of the first semiconductor substrate 10. The pre-solders 161a contain Sn in an amount ranging from about 80 wt % to about 96.5 wt %. In an embodiment, a material of the pre-solders 161a is SAC305 lead-free solder which contains Sn in an amount of about 96.5 wt %, and a melting point of which is about 217° C. In another embodiment, the material of the pre-solders 161a is a tin-indium-silver (SnInAg) alloy which contains Sn in an amount of about 90 wt %, and a melting point of which is about 205° C. In another embodiment, the material of the pre-solders 161a is an SnInAg alloy which contains Sn in an amount of about 80 wt %, and a melting point of which is about 176° C.

Referring to FIG. 6, an adhesive layer 19 is formed on a back surface 142 of the semiconductor die 14. The adhesive layer 19 may be formed, for example, by curing a liquid adhesive, or, for another example, the adhesive layer 19 may be a film structure. It is noted that the adhesive layer 19 may be omitted.

Referring to FIG. 7, a second semiconductor substrate 12 is provided. Then, solder balls 162a are formed on second bottom pads 124 disposed on a second lower surface 122 of the second semiconductor substrate 12. A melting point of the solder balls 162a is higher than a melting point of the pre-solders 161a disposed on the pads 103 of the first semiconductor substrate 10 (FIG. 5), and an amount of Sn contained in the pre-solders 161a (FIG. 5) is less than an amount of Sn contained in the solder balls 162a. The solder balls 162a contain Sn in an amount ranging from about 96.5 wt % to about 100 wt %. In one embodiment, the material of the solder balls 162a is pure Sn which contains Sn in an amount of about 100 wt %, and a melting point of which is about 232° C. In another embodiment, the material of the solder balls 162a is SAC305 (about 96.5 wt % Sn and a melting point of about 217° C.).

Referring to FIG. 8, the second semiconductor substrate 12 is disposed on the first semiconductor substrate 10. The upper surface 101 of the first semiconductor substrate 10 faces the lower surface 122 of the second semiconductor substrate 12, and ones of the solder balls 162a contact ones of the pre-solders 161a. In addition, a second lower dielectric layer 127 of the second semiconductor substrate 12 contacts the adhesive layer 19.

Referring to FIG. 9, a first heating process is conducted to cause the temperature to be a first working temperature between the melting point of the solder balls 162a and the melting point of the pre-solders 161a, so that the pre-solders 161a are softened and adhere to the respective solder balls 162a to form interconnection elements 16c. Meanwhile, the solder balls 162a are not softened, and remain solid. A portion of each pre-solder 161a extends upward along a periphery outer surface 164 of the respective solder ball 162a. Therefore, there is an actual boundary (a periphery outer surface 164) between the solder ball 162a and the pre-solder 161a, and the material of the solder ball 162a is different from the material of the pre-solder 161a. At this stage, the pre-solder 161a is cupped, and the solder ball 162a is approximately a sphere, positioned within the cupped pre-solder 161a. The curvature of the side surface of the solder ball 162a is discontinuous with a curvature of the side surface of the pre-solder 161a.

In this embodiment, the heating is accomplished through a thermal pressing process, and a high thermal capacity mold 2 is applied to press the second semiconductor substrate 12 and the first semiconductor substrate 10 together. The high thermal capacity mold 2 includes a bottom mold 21 and a top mold 22, and both are made of, for example, iron or steel. The bottom mold 21 contacts the first semiconductor substrate 10, and the top mold 22 contacts the second semiconductor substrate 12. The bottom mold 21 and the top mold 22 also provide energy to heat the first semiconductor substrate 10 and the second semiconductor substrate 12, respectively, to the first working temperature. The bottom mold 21 and the top mold 22 move relative to each other, so that, in this embodiment, the periphery outer surface 164 of the solder ball 162a contacts the first top pad 103, and a central portion of the pre-solder 161a is thereby extruded to climb upward along the periphery outer surface 164.

In this embodiment, during the pressing process, the adhesive layer 19 contacts and adheres to the second lower dielectric layer 127. It is noted that if the second lower dielectric layer 127 is omitted, the adhesive layer 19 contacts and adheres to the lower surface 122 of the second semiconductor substrate 12. The adhesive layer 19 can provide a buffer between the second semiconductor substrate 12 and the semiconductor die 14. In addition, the adhesive layer 19 is pressed during the pressing process, so that bubbles in the adhesive layer 19 will be discharged.

In this stage (FIG. 9), the solder balls 162a are not softened, so that they can provide standoff and prevent the second semiconductor substrate 12 from convex warpage during the heating process. Therefore, a bleeding of the encapsulant 18 (FIG. 10) after the molding process is prevented. In addition, a weight of a solder ball 162a is at least ten times greater than a weight of a respective pre-solder 161a. For example, the weight of each of the solder balls 162a is about fourteen to fifteen times a weight of the respective pre-solder 161a. Therefore, the amount of the pre-solder 161a is relatively small, and a risk of a bridge between the interconnection elements 16c is low.

The use of the high thermal capacity mold 2 can control the first working temperature of the heating process fairly precisely. In one embodiment, the heating process can be controlled at a temperature having a deviation value within ±3° C. In an embodiment, the first working temperature may be in a range of about 200° C. to about 225° C., for example, about 200° C., about 212° C. or about 225° C.

In one or more embodiments, the high thermal capacity mold 2 is not used, and the first semiconductor substrate 10 and the second semiconductor substrate 12 are transported into a reflow oven to conduct a reflow process.

Three non-limiting illustrative examples are provided next.

### Example 1

the material of the solder ball 162a is SAC305 with the melting point of about 217° C., the first working temperature of the heating process is about 200° C., and the material of the pre-solder 161a is an SnInAg alloy which contains Sn in an amount of about 80 wt %, the melting point of which is about 176° C.

### Example 2

the material of the solder ball 162a is pure Sn with the melting point of about 232° C., the first working temperature of the heating process is about 212° C., and the material of the pre-solder 161a is an SnInAg alloy which contains Sn in an amount of about 90 wt %, the melting point of which is about 205° C.

### Example 3

the material of the solder ball 162a is pure Sn with the melting point of about 232° C., the first working temperature of the heating process is about 225° C., and the material of the pre-solder 161a is SAC305 with the melting point of about 217° C.

Referring to FIG. 10, after the heating process, the interconnection elements 16c electrically and physically connect the first top pads 103 and the second bottom pads 124. An encapsulant 18 is applied to a space between the first semiconductor substrate 10 and the second semiconductor substrate 12 to encapsulate the semiconductor die 14 and the interconnection elements 16c. In this embodiment, the encapsulant 18 is a molding compound. In an embodiment in which the first upper dielectric layer 105 and the second lower dielectric layer 127 are of a similar material, an adhesion force between the first upper dielectric layer 105 and the encapsulant 18 is substantially the same as an adhesion force between the second lower dielectric layer 127 and the encapsulant 18. It is noted that if the second lower dielectric layer 127 and the first upper dielectric layer 105 are omitted, the encapsulant 18 adheres to both the upper surface 101 of the first semiconductor substrate 10 and the lower surface 122 of the second semiconductor substrate 12. If the first semiconductor substrate 10 and the second semiconductor substrate 12 are of a similar material, an adhesion force between the encapsulant 18 and the upper surface 101 is substantially the same as an adhesion force between the encapsulant 18 and the lower surface 122.

The encapsulant 18 includes accommodation spaces 181 to accommodate the interconnection elements 16c. Because the encapsulant 18 is applied after the interconnection elements 16c are formed, a profile of a sidewall of each accommodation space 181 is conformal to a respective interconnection element 16c, and the entire peripheral outer surface of the interconnection element 16c is in contact with the sidewall of the respective accommodation space 181. That is, the profile of each of the accommodation spaces 181 is defined by the respective interconnection element 16c. The encapsulant 18 includes fillers 182 of various radii. The fillers 182 are substantially uniformly distributed within the encapsulant 18.

In an embodiment, a working temperature of the molding stage is about 165° C. to about 175° C., which is lower than the melting point of the pre-solders 161a.

Subsequently, the encapsulant 18 is cured so that the profiles of the accommodation spaces 181 are fixed. In this embodiment, the solid solder balls 162a can provide standoff and prevent the second semiconductor substrate 12 from convex warpage. Therefore, the encapsulant 18 will not bleed on the second upper dielectric layer 126.

Solder (not shown) may be disposed on the first bottom pads 104 of the first semiconductor substrate 10 to form at least one bottom solder ball (not shown) similar to the bottom solder balls 20 in in FIG. 1. Then, a second heating stage is conducted at a second working temperature higher than the melting point of the solder (e.g., corresponding to the bottom solder balls 20) and the solder balls 162a. The solder melts (e.g., to form the bottom solder balls 20), and the pre-solders 161a and the respective solder balls 162a are molten and fused together to form an interconnection element 16. Thus, the semiconductor package structure 1 as shown in FIG. 1 is obtained.

In one or more embodiments, the pre-solders 161a and the solder balls 162 fully mix such that the interconnection element 16 contains a consistent material throughout its volume. In other embodiments, the pre-solders 161a and the solder balls 162 mix such that a consistent material is formed where the pre-solders 161a and the solder balls 162 contact prior to the second heating stage.

As shown in FIG. 1, because the interconnection element 16 is a monolithic component formed from the pre-solder 161a fused with the solder ball 162a, there is no longer a detectable boundary between the first portion 161 and the second portion 162 after the second heating stage. Further, because the molding compound is cured prior to the second heating stage and thus prior to the pre-solders 161a and respective solder balls 162a melting and fusing, each interconnection element 16 retains a profile of the respective accommodation space 181. That is, the profile of the solder ball 162a positioned on the cupped pre-solder 161a prior to the second heating stage is similar to the profile of the interconnection element 16 after the second heating stage. Thus, the first portion 161 and the second portion 162 are divided by a curved imaginary surface 163 similar to the actual boundary between the pre-solder 161a and the solder ball 162a prior to the second heating stage (FIG. 9).

In one or more embodiments, after the second heating process, the interconnection element 16 contains Sn in an amount ranging from about 95 wt % to about 99.8 wt %. In the above-mentioned Example 1, the SAC305 solder ball 162a contains 96.5 wt % of Sn, the SnInAg pre-solder 161a contains 80 wt % of Sn, and the weight of the solder ball 162a is fourteen times the weight of the pre-solder 161a. Therefore, the wt % of Sn in the interconnection element 16 is determined as in equation (1).

(14*96.5%+1*80%)/(14+1)=0.954=95.4% (1)

In the above-mentioned Example 2, the pure Sn solder ball 162a contains 100 wt % of Sn, the SnInAg pre-solder 161a contains 90 wt % of Sn, and the weight of the solder balls 162a is fourteen times the weight of the pre-solder 161a. Therefore, the wt % of Sn in the interconnection element 16 is determined as in equation (2).

(14*100%+1*90%)/(14+1)=0.9933=99.33% (2)

In the above-mentioned Example 3, the pure Sn solder ball 162a contains 100 wt % of Sn, the SAC305 pre-solder 161a contains 96.5 wt % of Sn, and the weight of the solder balls 162a is fourteen times the weight of the pre-solder 161a. Therefore, the wt % of Sn in the interconnection element 16 is determined as in equation (3).

(14*100%+1*96.5%)/(14+1)=0.9977=99.77% (3)

After the heating of FIG. 9 and the molding stage of FIG. 10, the interconnection element 16 as shown in FIG. 2 is obtained.

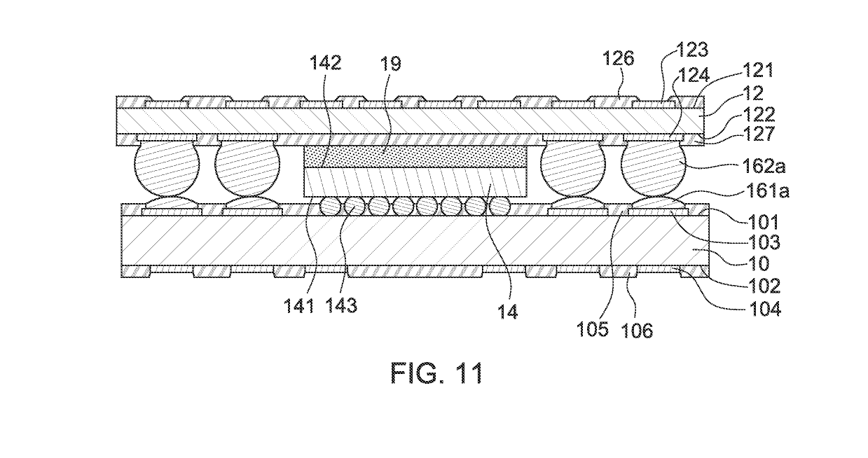

FIG. 11 illustrates a semiconductor manufacturing process according to an embodiment of the present disclosure. The initial stages of this embodiment are same as the stages shown in FIGS. 5 to 7, and the stage of FIG. 11 is subsequent to the stage of FIG. 7. FIG. 11 is similar to FIG. 8, except that the second semiconductor substrate 12 is misaligned with the first semiconductor substrate 10. That is, the second bottom pad 124 is not aligned with the first top pad 103, and there is a shift between the second bottom pad 124 and the first top pad 103. As can be seen, because the amount of the pre-solder 161a is relatively small, the risk of a bridge forming to an adjacent interconnection element 16 is low even when misalignment occurs. A the heating stage as in FIG. 9 and a molding stage as in FIG. 10 are next performed, to obtain a semiconductor package structure similar to the one illustrated in FIG. 10, but with the interconnection element 16b as shown in FIG. 4. As shown in FIG. 4, the interconnection element 16b is not symmetrical about a vertical axis.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor package structure, comprising:
a first semiconductor substrate including at least one first top pad;
a second semiconductor substrate including at least one second bottom pad corresponding to a respective first top pad;
a semiconductor die electrically connected to the first semiconductor substrate;
at least one interconnection element connecting the second bottom pad and the first top pad, wherein the interconnection element includes a first portion and a second portion, the first portion is cupped and is connected to the first top pad, the second portion is arcuate and is connected to the second bottom pad, and the first portion and the second portion together define the interconnection element as a monolithic component; and
an encapsulant disposed between the first semiconductor substrate and the second semiconductor substrate, wherein the encapsulant surrounds the interconnection element and defines an accommodation space, a profile of the accommodation space is defined by the first portion and the second portion, and the profile along the second portion has a shape of a solder ball in an unmelted state.

2. The semiconductor package structure according to claim 1, wherein at least a majority by weight of the interconnection element corresponds to the second portion.

3. The semiconductor package structure according to claim 2, wherein a weight of the second portion is greater than ten times a weight of the first portion.

4. The semiconductor package structure according to claim 2, wherein a material of the first portion is the same as a material of the second portion.

5. The semiconductor package structure according to claim 1, wherein a curvature of a side surface of the second portion is discontinuous with a curvature of a side surface of the first portion.

6. The semiconductor package structure according to claim 1, wherein a lateral maximum width of the second portion is greater than or equal to a lateral maximum width of the first portion.

7. The semiconductor package structure according to claim 1, wherein the interconnection element contains Sn in an amount ranging from about 95 wt % to about 99.8 wt %.

8. The semiconductor package structure according to claim 1, wherein there is an offset between a geometrical central axis of the first top pad and a geometrical central axis of the second portion.

9. The semiconductor package structure according to claim 1, further comprising an adhesive layer disposed between a back surface of the semiconductor die and the second semiconductor substrate.

10. A semiconductor package structure, comprising:
a first semiconductor substrate including at least one first top pad;
a second semiconductor substrate including at least one second bottom pad corresponding to a respective first top pad;
a semiconductor die electrically connected to the first semiconductor substrate;
at least one interconnection element connecting the second bottom pad and the first top pad, wherein a material of the interconnection element is consistent throughout a volume of the interconnection element, and wherein the material includes Sn in an amount ranging from about 95 wt % to about 99.8 wt %; and
an encapsulant disposed between the first semiconductor substrate and the second semiconductor substrate, and covering the semiconductor die and the interconnection element to define an accommodation space, a profile of the accommodation space defined by the interconnection element, and the profile along an upper portion of the interconnection element having a shape of a solder ball in an unmelted state.

11. The semiconductor package structure according to claim 10, wherein a side surface of the interconnection element includes an upper side surface and a lower side surface, and a curvature of the upper side surface is discontinuous with a curvature of the lower side surface.

12. The semiconductor package structure according to claim 10, wherein there is an offset between a geometrical central axis of the first top pad and a geometrical central axis of the interconnection element.

13. The semiconductor package structure according to claim 10, further comprising an adhesive layer disposed between a back surface of the semiconductor die and the second semiconductor substrate.

14. The semiconductor package structure according to claim 10, wherein the interconnection element is not symmetrical around a vertical axis.

15-21. (canceled)

22. A semiconductor package structure, comprising:
a first substrate including a first pad;
a second substrate including a second pad;
an interconnection element extending between the first pad and the second pad, wherein the interconnection element includes a first portion and a second portion, the first portion is adjacent to the first pad, the second portion is adjacent to the second pad, the first portion and the second portion together define the interconnection element as a monolithic component, and a curvature of a side surface of the first portion is discontinuous with a curvature of a side surface of the second portion; and
an encapsulant disposed between the first substrate and the second substrate, and covering the side surface of the first portion and the side surface of the second portion to define an accommodation space, a profile of the accommodation space defined by the first portion and the second portion, and the profile along the second portion having a shape of a solder ball in an unmelted state.

23. The semiconductor package structure according to claim 22, further comprising a semiconductor die electrically connected to the first substrate.

24. The semiconductor package structure according to claim 23, further comprising an adhesive layer disposed between the semiconductor die and the second substrate.

25. The semiconductor package structure according to claim 22, wherein the second portion corresponds to at least a majority by volume of the interconnection element.

26. The semiconductor package structure according to claim 22, wherein a lateral maximum width of the second portion is greater than a lateral maximum width of the first portion.

27. The semiconductor package structure according to claim 22, wherein the interconnection element includes Sn in an amount ranging from about 95 wt % to about 99.8 wt %.
